(19) United States
(12) Patent Application Publication
(10) Pub. No.: US 2026/0052973 A1
(43) Pub. Date: Feb. 19, 2026

(54) CONFIGURABLE BONDING PAD ROUTING

(71) Applicant: QUALCOMM Incorporated, San Diego, CA (US)

(72) Inventors: Jonghae KIM, San Diego, CA (US); Ranadeep DUTTA, Del Mar, CA (US); Je-Hsiung LAN, San Diego, CA (US)

(21) Appl. No.: 18/807,506

(22) Filed: Aug. 16, 2024

(51) Int. Cl. H01L 23/528; H01L 23/00; H01L 23/522; H01L 25/065

(52) U.S. Cl. CPC H01L 23/5286; H01L 23/5226; H01L 23/5283; H01L 24/08; H01L 24/80; H01L 24/16; H01L 25/0657; H01L 2224/08145; H01L 2224/16145; H01L 2224/80895; H01L 2224/80896; H01L 2225/06527; H01L 2924/1011

(57) ABSTRACT

Various aspects of the present disclosure generally relate to a bonding pad configuration. A device includes a die including multiple bonding pads, pad configuration circuitry, and control circuitry. The pad configuration circuitry is configured to, based on a routing configuration, selectively connect multiple nodes of first circuitry to a first set of bonding pads of the multiple bonding pads. The control circuitry is connected to the pad configuration circuitry and configured to obtain the routing configuration.

### FIELD

Various features relate to a die having configurable bonding pad routing.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Copper-to-copper (Cu-to-Cu) hybrid bonding is a technology that uses metal contacts between dielectric materials to create a 3D stacked semiconductor device. The Cu-to-Cu hybrid bonding supports high bonding pad (e.g., input/output (I/O) pads) counts by having small contact sizes and ultra-fine contact pitch. However, the Cu-to-Cu hybrid bonding may result in one or more defective bonding pad connections thereby resulting in less than a 100% bonding pad process yield. In some situations, the one or more defective bonding pad connections may render an entire device defective and unusable depending on the extent of the defects. To account for defective bonding pad connections, conventional dies configured for Cu-to-Cu hybrid bonding typically include redundancy in which multiple (e.g., three) bonding pads are provided in parallel for each interconnect/signal path. Accordingly, when a set of three bonding pads is provided in parallel for each interconnect/signal path, the device is still usable if the set of three bonding pads has one or two defective bonding pads. However, including such redundancy into each die of a device increases design interconnect routing complexity, materials, size, and cost.

### SUMMARY

Various features relate to integrated circuit devices.

One example provides a device that includes a die. The die includes first circuitry including multiple nodes. The die also includes multiple bonding pads including a first plurality of bonding pads. The die further includes pad configuration circuitry configured to, based on a routing configuration, selectively connect the multiple nodes of the first circuitry to a first set of bonding pads of the first plurality of bonding pads. The die includes control circuitry connected to the pad configuration circuitry. The control circuitry is configured to obtain the routing configuration.

Another example provides a method of fabrication. The method includes obtaining a first die. The first die includes first circuitry including first nodes. The first die also includes multiple bonding pads including a first plurality of bonding pads. The first die further includes first pad configuration circuitry configured to selectively connect the first multiple nodes of the first circuitry to a first set of bonding pads of the first plurality of bonding pads of the first die. The method also includes communicatively coupling the first die to a second die. The second die includes second circuitry including second nodes. The second die also includes multiple bonding pads including a second plurality of bonding pads. The second die further includes second pad configuration circuitry configured to selectively connect the second multiple nodes of the second circuitry to a first set of bonding pads of the second plurality of bonding pads of the second die.

Another example provides a method of operation of a stack of dies. The method includes obtaining a first routing configuration associated with first multiple nodes of first circuitry of a first die and a first plurality of bonding pads of the first die. The first die is communicatively coupled to a second die. The method also includes selectively connecting, based on the first routing configuration, the first multiple nodes of the first circuitry to a first set of bonding pads of the first plurality of bonding pads of the first die.

Another example provides a device that includes a stack of dies. The stack of dies includes a first die and a second die communicatively coupled to the first die. The first die includes first circuitry including first nodes. The first die also includes multiple bonding pads including a first plurality of bonding pads. The first die further includes first pad configuration circuitry configured to selectively connect the first multiple nodes of the first circuitry to a first set of bonding pads of the first plurality of bonding pads of the first die. The second die includes second circuitry including second nodes. The second die also includes multiple bonding pads including a second plurality of bonding pads. The second die further includes second pad configuration circuitry configured to selectively connect the second multiple nodes of the second circuitry to a first set of bonding pads of the second plurality of bonding pads of the second die.

Another example provides a method of fabrication of a die. The method includes forming first circuitry including multiple nodes. The method also includes forming multiple bonding pads including a first plurality of bonding pads. The method further includes forming control circuitry configured to obtain a routing configuration. The method includes forming pad configuration circuitry connected to the control circuitry and configured to, based on the routing configuration, selectively connect the multiple nodes of the first circuitry and a first set of bonding pads of the first plurality of bonding pads.

Another example provides a method of fabrication of a stack of dies. The method includes communicatively coupling a first die to a second die. The first die includes first circuitry including first nodes. The first die also includes multiple bonding pads including a first plurality of bonding pads. The first die further includes first pad configuration circuitry configured to selectively connect the first multiple nodes of the first circuitry to a first set of bonding pads of the first plurality of bonding pads of the first die. The second die includes second circuitry including second nodes. The second die also includes multiple bonding pads including a second plurality of bonding pads. The second die further includes second pad configuration circuitry configured to selectively connect the second multiple nodes of the second circuitry to a first set of bonding pads of the second plurality of bonding pads of the second die.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1 illustrates a cross-sectional profile view of an exemplary device that includes configurable bonding pad routing.

FIG. 2 illustrates a top view of a particular implementation of the exemplary device of FIG. 1.

FIG. 3 illustrates a cross-sectional profile view of a particular implementation of a device that includes the exemplary device of FIG. 1.

FIG. 4 illustrates an example of a device that includes configurable bonding pad routing.

FIG. 5 illustrates examples of different routing configurations of a device having configurable bonding pad routing.

FIG. 6 illustrates a cross-sectional profile view of a particular implementation of a device that includes configurable bonding pad routing.

FIG. 7 illustrates a cross-sectional profile view of a particular implementation of a device that includes configurable bonding pad routing.

FIG. 8 illustrates an exemplary sequence for fabricating an exemplary device that includes configurable bonding pad routing.

FIG. 9 illustrates an exemplary flow diagram of a method of semiconductor fabrication for a device that includes a configurable bonding pad routing.

FIG. 10 illustrates an exemplary flow diagram of a method of semiconductor fabrication for a device that includes a configurable bonding pad routing.

FIG. 11 illustrates an exemplary flow diagram of a method of operation of a stack of dies that includes configurable bonding pad routing.

FIG. 12 illustrates various electronic devices that may integrate an exemplary device that includes configurable bonding pad routing as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. As used herein, “stacked dies” and/or “stacked ICs” refer to arrangements in which one die (e.g., a first die) is disposed over (including directly over) another die (e.g., a second die). Additionally, a three-dimensional integrated circuit (3D IC) includes a set of stacked and interconnected dies. Generally, a 3D IC architecture can achieve higher performance, increased functionality, lower power consumption, and/or smaller footprint, as compared to providing the same circuitry in a monolithic die or in a two-dimensional (2D) IC structure.

In some implementations of stacked ICs, copper-to-copper (Cu-to-Cu) hybrid bonding is a technology that uses metal contacts between dielectric materials to create a 3D stacked semiconductor device. To illustrate, conventional designs for dies to be used with Cu-to-Cu hybrid bonding include redundancy in which multiple (e.g., three) bonding pads are provided in parallel for each interconnect/signal path. Unfortunately, including such redundancy increases design interconnect routing complexity, materials, size, and cost of the dies. Various aspects of the present disclosure provide configurable bonding pad routing.

Aspects of the present disclosure are directed to configurable bonding pad routing. In some aspects, a die includes first circuitry including multiple nodes, and multiple bonding pads including a first plurality of bonding pads. Each node of the multiple nodes may be configured as an input node, an output node, or an input/output node. The die also includes pad configuration circuitry configured to, based on a routing configuration, selectively connect the multiple nodes of the first circuitry to a first set of bonding pads of the first plurality of bonding pads. Accordingly, routing of a conductive path between the multiple nodes and the first plurality of bonding pads can be selectively configured by the pad configuration circuitry.

In some implementations, a stack of dies includes the die (e.g., a first die) that is communicatively coupled to a second die. For example, the stack of dies may include a Cu-to-Cu hybrid bonding chip stack in which bonding pads of the first and second dies are coupled together using a Cu-to-Cu hybrid bonding process. The second die includes second circuitry including second nodes, and multiple bonding pads including a second plurality of bonding pads. The second die further includes second pad configuration circuitry configured to selectively connect the second multiple nodes of the second circuitry to a first set of bonding pads of the second plurality of bonding pads of the second die. In some implementations, the first die also includes control circuitry connected to the pad configuration circuitry, and configured to obtain the routing configuration. To illustrate, the first die (e.g., the control circuitry) may initiate a test operation between the first die and the second die to detect whether a conductive path associated with a bonding pad is defective or available for use. For example, the test operation may be initiated based on power-up of the die, power-up of the second die, expiration of a time period, or on detection of a failure of a conductive path between the first die and the second die. Based on a result of the test operation, the first die (e.g., the control circuitry) generates the routing configuration and configures the first circuitry based on the routing configuration to selectively connect the multiple nodes of the first circuitry to the first set of bonding pads of the first plurality of bonding pads.

The disclosed device, such as the die or the stack of dies, with the configurable bonding pad routing provides configurable (or reconfigurable) routing of conductive paths between nodes and bonding pads of at least one die of the device. The ability to selectively establish the conductive paths provides routing flexibility to compensate for one or more defects form a Cu-to-Cu hybrid bonding process or one or more bonding pad failures during operation of the device. Additionally, the disclose device provides configurable bonding pad routing flexibility that can result in fewer bonding pads as compared to a die that implements conventional redundant bonding pads in parallel. Having fewer bonding pads as compared to the die that implements conventional redundant bonding pads in parallel can reduce design interconnect routing complexity, an amount of materials, a size, and a cost of the device.

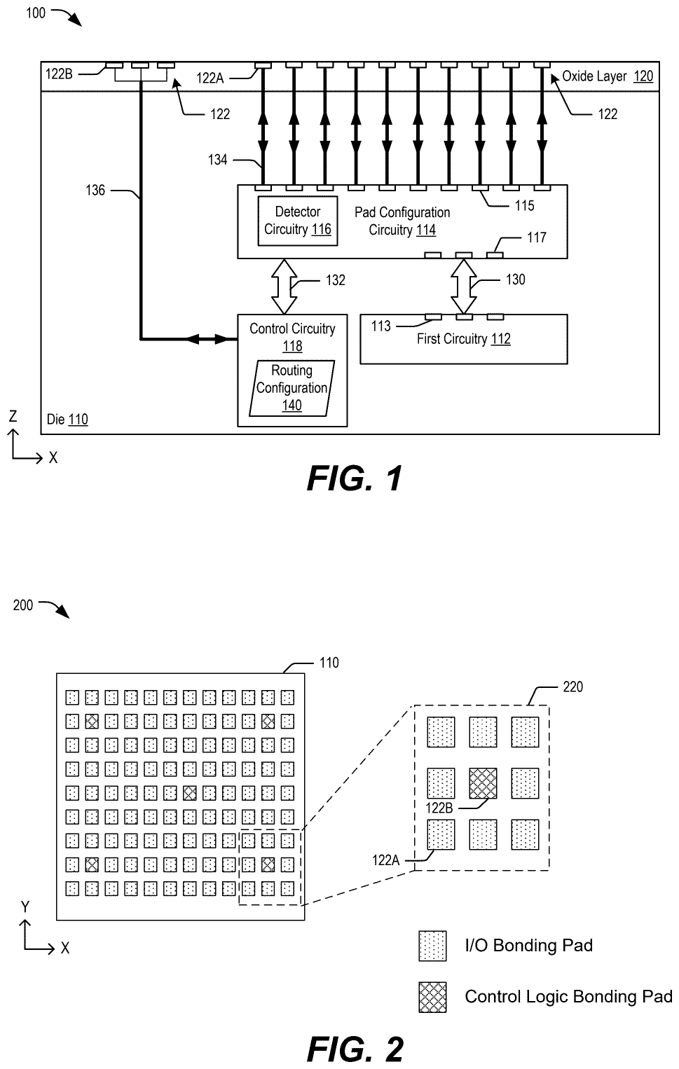

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 1, multiple bonding pads are illustrated and associated with reference numbers 122A and 122B. When referring to a particular one of these bonding pads, such as a bonding pad 122A, the distinguishing letter “A” is used. However, when referring to any arbitrary one of these bonding pads or to these bonding pads as a group, the reference number 122 is used without a distinguishing letter.

### Exemplary Devices Including Configurable Bonding Pad Routing

FIG. 1 illustrates a cross-sectional profile view of an exemplary device 100 that includes configurable bonding pad routing. In the implementation shown in FIG. 1, the device 100 includes a die 110. Unless otherwise specifically noted herein, “configurable” should be understood to include reconfigurable.

The die 110 can include integrated circuitry, such as a plurality of transistors and/or other circuit elements arranged and interconnected to form logic cells, memory cells, etc., as described further herein. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The die 110 may include or correspond to a particular IC device that can be arranged and interconnected as a three-dimensional (3D) IC device. In some implementations, the die 110 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the die 110. Additionally, or alternatively, the die 110 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, the IC die is electrically connected to, or integrated with, a respective substrate. For example, the die 110 may be electrically connected (e.g., via one or more contacts or interconnects) to a substrate. One or more of the conductive interconnects and contacts described herein can include, for example, microbumps, conductive pillars, conductive pads (e.g., for pad-to-pad bonding), or other similar chiplet-to-chiplet interconnect contacts used for 3D chiplet stacking.

The die 110 includes first circuitry 112, pad configuration circuitry 114, and control circuitry 118. The first circuitry 112 includes multiple nodes 113. The pad configuration circuitry 114 includes a first set of nodes 115, a second set of nodes 117, and detector circuitry 116.

The first circuitry 112 is connected to the pad configuration circuitry 114. For example, the first circuitry 112 is communicatively coupled to the pad configuration circuitry 114 with a set of conductive paths 130, such as one or more communication paths. To illustrate, each node of the multiple nodes 113 of the first circuitry 112 is communicatively coupled to a corresponding node of the second set of nodes 117 of the pad configuration circuitry 114 via a respective conductive path of the set of conductive paths 130.

The control circuitry 118 is connected to the pad configuration circuitry 114. For example, the control circuitry 118 is communicatively coupled to the pad configuration circuitry 114 with a set of conductive paths 132, such as one or more communication paths. It is noted that, although the control circuitry 118 is described as being separate from the first circuitry 112 or the pad configuration circuitry 114, in other implementations, the first circuitry 112 or the pad configuration circuitry 114 can include the control circuitry 118.

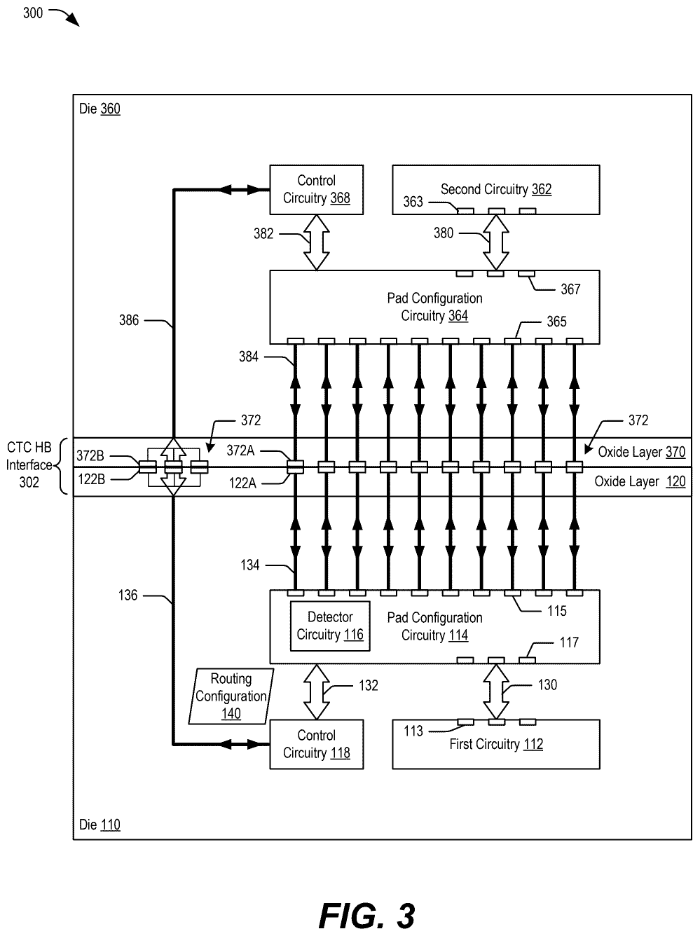

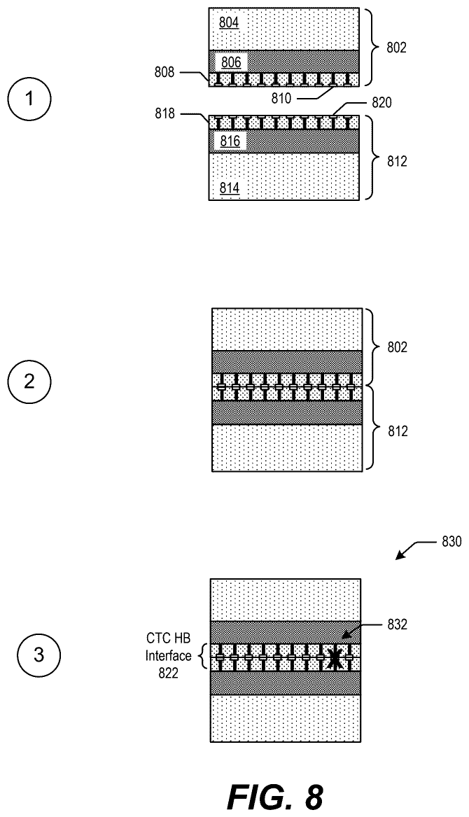

The die 110 also includes multiple bonding pads 122. The multiple bonding pads 122 may include a first plurality of bonding pads that include a representative first bonding pad 122A, and a second plurality of bonding pads that include a representative second bonding pad 122B. In some implementations, a total number of bonding pads of the first plurality of bonding pads 122A is less than three times a total number of nodes of the multiple nodes 113 of the first circuitry 112. Additionally, or alternatively, the die 110 may also include an oxide layer 120 that includes the multiple bonding pads 122. The oxide layer 120, the multiple bonding pads 122, or a combination thereof, may be configured for Cu-to-Cu hybrid bonding. For example, the oxide layer 120, the multiple bonding pads 122, or a combination thereof of the die 110 may be configured to be bonded to another die, as described further herein at least with reference to FIGS. 3 and 8.

The first plurality of bonding pads 122A are connected to the pad configuration circuitry 114. For example, the first plurality of bonding pads 122A are communicatively coupled to the pad configuration circuitry 114 with multiple conductive paths 134. Each conductive path of the multiple conductive paths 134 corresponds to a different bonding pad of the first plurality of bonding pads 122A. In some implementations, each conductive path of the multiple conductive paths 134 includes the corresponding bonding pad of the first plurality of bonding pads 122A that the conductive path is connected to.

The second plurality of bonding pads 122B is connected to the control circuitry 118. For example, the second plurality of bonding pads 122B are communicatively coupled to the control circuitry 118 with one or more conductive paths 136. The second plurality of bonding pads 122B is configured to enable communication between the control circuitry 118 of the die 110 and control circuitry of another die coupled to the die 110. For example, the control circuitry 118 may communicate with the control circuitry of the other die to synchronize communication between the die and the other die, as described further herein at least with reference to FIG. 3. In some implementations, the two or more bonding pads of the second plurality of bonding pads 122B are configured in parallel such that redundancy is provided in the event of a defect or failure of one of the two or more bonding pads.

The pad configuration circuitry 114 is connected to the first plurality of bonding pads 122A. For example, the pad configuration circuitry 114 is communicatively coupled to the first plurality of bonding pads 122A with multiple conductive paths 134, such as multiple communication paths. To illustrate, each node of the first set of nodes 115 of the pad configuration circuitry 114 is communicatively coupled to a corresponding bonding pad of the first plurality of bonding pads 122A via a respective conductive path of the multiple conductive paths 134.

The control circuitry 118 is configured to obtain a routing configuration 140. The routing configuration 140 may indicate a configuration of the pad configuration circuitry 114 to connect a portion of the first set of nodes 115 and the second set of nodes 117 to selectively connect the multiple nodes 113 of the first circuitry 112 to the set of bonding pads of the first plurality of bonding pads 122A. Additionally, or alternatively, the routing configuration 140 may indicate the set of bonding pads of the first plurality of bonding pads 122A, and for each node of the multiple nodes 113, a corresponding bonding pad of the set of bonding pads.

To obtain the routing configuration 140, the control circuitry 118 may perform a test operation with (e.g., between) another die that is coupled to the die 110. The test operation may be configured to identify one or more defective bonding pads of the first plurality of bonding pads 122A and/or one or more defective conductive paths of the conductive paths 134. For example, the control circuitry 118 is configured to initiate the test operation based on power-up of the die 110, power-up of the second die 360, expiration of a time period (e.g., a number of operational clock cycles, daily, weekly, or other specified time period), detection of a failure of a conductive path between the die and the other die, or a combination thereof.

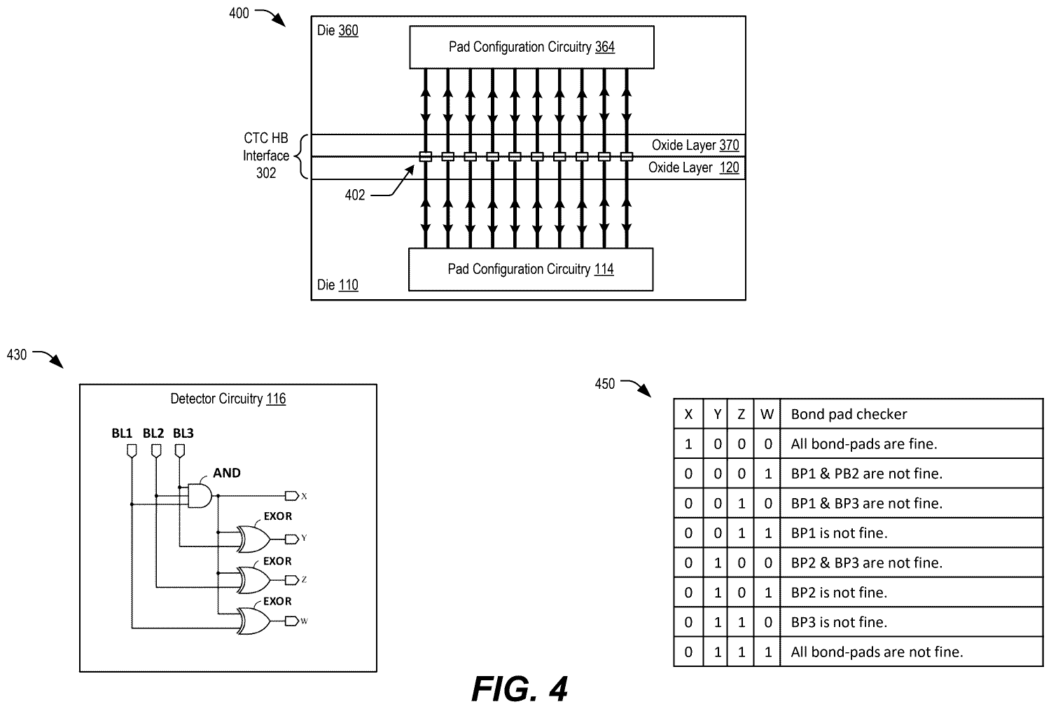

To perform the test operation, the control circuitry 118 causes the detector circuitry 116 of the pad configuration circuitry 114 to generate test data that indicates one or more defective conductive paths and/or bonding pads, one or more available conductive paths and/or bonding pads, or a combination thereof. To illustrate, the detector circuitry 116 may be configured to communicate with the other die to send test signals via the conductive paths 134 and the first plurality of bonding pads 122A to identify one or more defective conductive paths and/or bonding pads. For example, the detector circuitry 116 may be configured to receive, from the other die, a first signal via a first conductive path of the conductive paths 134 that is coupled to or includes a bonding pad of the first plurality of bonding pads 122A. The detector circuitry 116 may generate test data that indicates whether the first conductive path (e.g., the bonding pad) is defective or available for use. An example of the detector circuitry 116 is described further herein at least with reference to FIG. 4.

The control circuitry 118 may obtain the routing configuration 140 based on the test operation. For example, the control circuitry 118 may obtain the routing configuration 140 from the other die. Additionally, or alternatively, the control circuitry 118 may generate the routing configuration 140. For example, the control circuitry 118 may generate the routing configuration 140 based on a mapping table, one or more routing constraints associated with the multiple nodes 113, or a combination thereof. As another example, the control circuitry 118 may provide the test data to a machine learning (ML) model that is trained to generate the routing configuration 140. In some implementations, the routing configuration 140 is generated to optimize signal routing, such as by determining shortest path routings. The control circuitry 118 may provide the routing configuration 140 to the pad configuration circuitry 114.

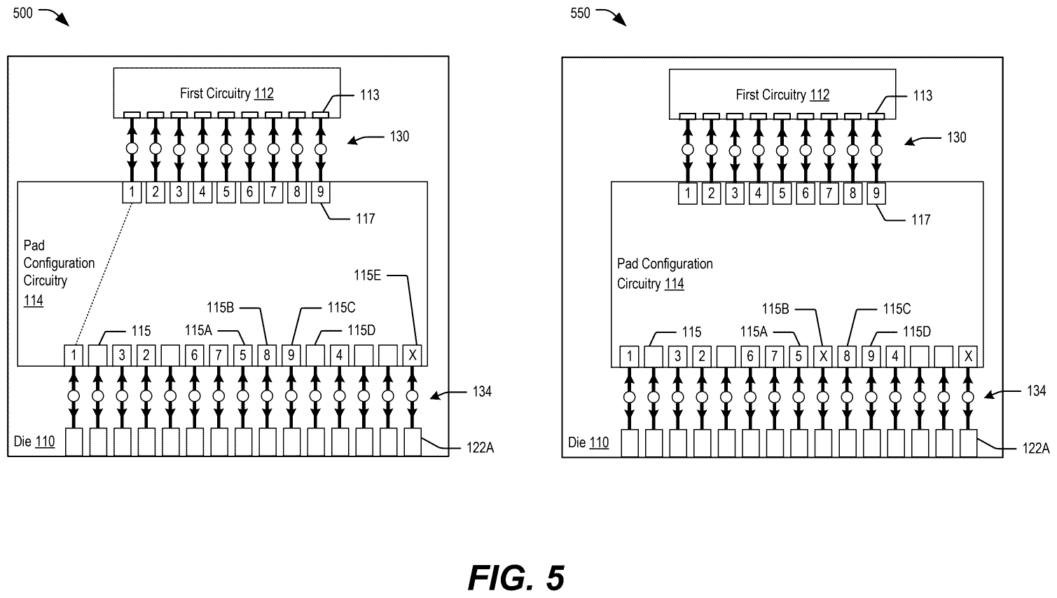

The pad configuration circuitry 114 is configured to connect the multiple nodes 113 of the first circuitry 112 to a set of bonding pads of the first plurality of bonding pads 122A. For example, the pad configuration circuitry 114 can be configured to connect the multiple nodes 113 of the first circuitry 112 to the set of bonding pads of the first plurality of bonding pads 122A based on the routing configuration 140. To illustrate, the pad configuration circuitry 114 may configure one or more connections, within the pad configuration circuitry 114, between a portion of the first set of nodes 115 and the second set of nodes 117 to selectively connect the multiple nodes 113 of the first circuitry 112 to the set of bonding pads of the first plurality of bonding pads 122A. To configure the one or more connections, the pad configuration circuitry 114 may include one or more switches or circuits, such as an array of switches, gates, multiplexers, other components, the like, or a combination thereof. In some implementations, the pad configuration circuitry 114 is reconfigurable to selectively connect the multiple nodes 113 of the first circuitry 112 to a first set of bonding pads of the first plurality of bonding pads 122A or a second set of bonding pads of the first plurality of bonding pads 122A, where the first set of bonding pads is different from the second set of bonding pads. Operation of the pad configuration circuitry 114 to selectively connect the multiple nodes 113 of the first circuitry 112 to the set of bonding pads of the first plurality of bonding pads 122A is described further herein at least with reference to FIG. 5.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein.

In some implementations, the device 100 can be integrated in a smartphone, a tablet computer, a fixed location terminal device, an automobile, a wearable electronic device, a laptop computer, or some combination thereof, as described in more detail below with reference to FIG. 12. While FIG. 1 illustrates an example device that is a single die, in other examples, one or more additional integrated devices, packages, or some combination thereof can be present in a stacked integrated circuit without departing from the scope of the subject disclosure. Further, the device 100 of FIG. 1 can be integrated with or included within a wide variety of other devices. For example, a device that includes the die 110 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SIC) based integrated device, a memory, power management processor, and/or combinations thereof. In such devices, the die 110 can operate as any of these components (or a combination of these components) that includes active circuitry.

The device 100 thus provides configurable routing of conductive paths between nodes and bonding pads of at least one die of the device as compared to other conventional dies that utilize redundant bonding pads in parallel. The configurable bonding pad routing provides routing flexibility to compensate for one or more defects from a Cu-to-Cu hybrid bonding process or one or more bonding pad failures during operation of the device. Accordingly, the die 110 can dynamically reconfigure the bonding pad routing, which may result in a life of the die 110 (or the device 100) being extended as compared to a conventional die that implements conventional redundant bonding pads in parallel. Additionally, or alternatively, the configurable bonding pad routing enables the device 100 to have fewer bonding pads as compared to a conventional die that implements conventional redundant bonding pads in parallel. Having fewer bonding pads as compared to the die that implements conventional redundant bonding pads in parallel can reduce design interconnect routing complexity, an amount of materials, a size, and a cost of the device. Additionally, or alternatively, the configurable bonding pad routing enables to the device 100 to optimize signal routing to bonding pads and dynamically select short paths rather than being limited to a fixed path allocation as with the conventional die that implements conventional redundant bonding pads in parallel.

In a particular implementation, the device 100 includes a die (e.g., the die 110). The die (e.g., the die 110) includes first circuitry (e.g., the first circuitry 112) including multiple nodes (e.g., the multiple nodes 113). The die (e.g., the die 110) also includes multiple bonding pads (e.g., the multiple bonding pads 122) including a first plurality of bonding pads (e.g., the first plurality of bonding pads 122A). The die (e.g., the die 110) further includes pad configuration circuitry (e.g., the pad configuration circuitry 114) configured to, based on a routing configuration (e.g., the routing configuration 140), selectively connect the multiple nodes (e.g., the multiple nodes 113) of the first circuitry (e.g., the first circuitry 112) to a first set of bonding pads of the first plurality of bonding pads (e.g., the first plurality of bonding pads 122A). The die (e.g., the die 110) includes control circuitry (e.g., the control circuitry 118) connected to the pad configuration circuitry (e.g., the pad configuration circuitry 114). The control circuitry (e.g., the control circuitry 118) is configured to obtain the routing configuration (e.g., the routing configuration 140).

Referring to FIG. 2, FIG. 2 illustrates a top view of the exemplary device 100 of FIG. 1. The top view shows an example of an array of the multiple bonding pads 122. The array of the multiple bonding pads 122 includes the first plurality of bonding pads 122A and the second plurality of bonding pads 122B. The first plurality of bonding pads 122A is associated with bonding pads configured to be coupled to the multiple nodes 113 of the first circuitry 112. The second plurality of bonding pads 122B is associated with control logic bonding pads configured to be coupled to the control circuitry 118. An example of a detail of a portion (e.g., a pin group) of the array of the multiple bonding pads 122 is shown at 220. As shown in FIG. 2, the second plurality of bonding pads 122B are positioned throughout the array of the multiple bonding pads 122.

FIG. 3 illustrates a cross-sectional profile view of a particular implementation of a device 300 that includes the exemplary device 100 of FIG. 1. The device 300 of FIG. 3 includes the die 110 (also referred to herein as the “first die 110”) and a second die 360. For example, the device 300 may include a chip stack that includes the first die 110 communicatively coupled to the second die 360. The second die 360 may include one or more components described with reference to the first die 110, as discussed further herein. In some implementations, the second die 360 includes all of the same features and components as the first die 110 as described with reference to FIGS. 1 and 2. In some other implementations, the second die 360 may include one or more fewer or different components as the first die 110, as described with reference to FIGS. 1 and 2.

The second die 360 can include integrated circuitry, such as a plurality of transistors and/or other circuit elements arranged and interconnected to form logic cells, memory cells, etc., as described further herein. Components of the integrated circuitry can be formed in and/or over a semiconductor substrate. Different implementations can use different types of transistors, such as an FET, a planar FET, a finFET, a gate all around FET, or mixtures of transistor types. In some implementations, an FEOL process may be used to fabricate the integrated circuitry in and/or over the semiconductor substrate.

The second die 360 may include or correspond to a particular IC device that can be arranged and interconnected as a 3D IC device. In some implementations, the second die 360 includes one or more microcontrollers, ASICs, FPGAs, CPUs having one or more processing cores, processing systems, SoCs, or other circuitry and logic configured to facilitate the operations of the second die 360. Additionally, or alternatively, the second die 360 may include or be operated as a memory, such as an SRAM, a DRAM, flash memory, ROM, PROM, EPROM, EEPROM, an SSD, or a combination thereof.

In some implementations, the second die 360 may be electrically connected (e.g., via one or more contacts or interconnects) to a substrate. One or more of the conductive interconnects and contacts described herein can include, for example, microbumps, conductive pillars, conductive pads (e.g., for pad-to-pad bonding), or other similar chiplet-to-chiplet interconnect contacts used for 3D chiplet stacking.

The second die 360 includes second circuitry 362, pad configuration circuitry 364, and control circuitry 368. The second circuitry 362 may include one or more components, or may be configured to operate, as described with reference to the first circuitry 112. The second circuitry 362 includes multiple nodes 363. The pad configuration circuitry 364 may include or correspond to the pad configuration circuitry 114. The pad configuration circuitry 364 includes a first set of nodes 365 and a second set of nodes 367. In some implementations, the pad configuration circuitry 364 may also include detector circuitry. For example, the detector circuitry of the pad configuration circuitry 364 may include one or more components, or may be configured to operate, as described with reference to the detector circuitry 116.

The second circuitry 362 is connected to the pad configuration circuitry 364. For example, the second circuitry 362 is communicatively coupled to the pad configuration circuitry 364 with a set of conductive paths 380, such as one or more communication paths. To illustrate, each node of the multiple nodes 363 of the second circuitry 362 is communicatively coupled to a corresponding node of the second set of nodes 367 of the pad configuration circuitry 364 via a respective conductive path of the set of conductive paths 380.

The control circuitry 368 may include one or more components, or may be configured to operate, as described with reference to the control circuitry 118. The control circuitry 368 is connected to the pad configuration circuitry 364. For example, the control circuitry 368 is communicatively coupled to the pad configuration circuitry 364 with a set of conductive paths 382, such as one or more communication paths. It is noted that, although the control circuitry 368 is described as being separate from the second circuitry 362 or the pad configuration circuitry 364, in other implementations, the second circuitry 362 or the pad configuration circuitry 364 can include the control circuitry 368.

The second die 360 also includes multiple bonding pads 372. The multiple bonding pads 372 may include a first plurality of bonding pads that include a representative first bonding pad 372A, and a second plurality of bonding pads that include a representative second bonding pad 372B. Additionally, or alternatively, the second die 360 may also include an oxide layer 370 that includes the multiple bonding pads 372. In some implementations, a total number of bonding pads of the first plurality of bonding pads 372A is less than three times a total number of nodes of the multiple nodes 363 of the second circuitry 362. The oxide layer 370, the multiple bonding pads 372, or a combination thereof, may be configured for Cu-to-Cu hybrid bonding. For example, the oxide layer 370, the multiple bonding pads 372, or a combination thereof of the second die 360 may be configured to be bonded to another die, such as the first die 110.

The second die 360 is communicatively coupled to the die 110. For example, the first die 110 is communicatively coupled to the second die 360 based on a copper-to-copper hybrid bonding (CTC HB) process. The CTC HB process may generate a CTC HB interface 302 in which the second die 360 is communicatively coupled to the first die 110. To illustrate, one or more of the multiple bonding pads 372 of the second die 360 may be communicatively coupled to one or more of the multiple bonding pads 122 of the first die 110. Additionally, the second die 360 may be coupled (e.g., non-communicatively coupled) to the first die 110. To illustrate, the oxide layer 370 of the second die 360 may be coupled to the oxide layer 120 of the first die 110 based on the CTC HB process.

The first plurality of bonding pads 372A are connected to the pad configuration circuitry 364. For example, the first plurality of bonding pads 372A are communicatively coupled to the pad configuration circuitry 364 with multiple conductive paths 384. Each conductive path of the multiple conductive paths 384 corresponds to a different bonding pad of the first plurality of bonding pads 372A. In some implementations, each conductive path of the multiple conductive paths 384 includes the corresponding bonding pad of the first plurality of bonding pads 372A that the conductive path is connected to.

The second plurality of bonding pads 372B is connected to the control circuitry 368. For example, the second plurality of bonding pads 372B are communicatively coupled to the control circuitry 368 with one or more conductive paths 386. The second plurality of bonding pads 372B is configured to enable communication between the control circuitry 368 of the second die 360 and the control circuitry 118 of the first die 110 that is coupled to the second die 360. For example, the control circuitry 368 may communicate with the control circuitry 118 of the first die 110 to synchronize communication between the second die 360 and the first die 110. In some implementations, the two or more bonding pads of the second plurality of bonding pads 372B are configured in parallel such that redundancy is provided in the event of a defect or failure of one of the two or more bonding pads.

The pad configuration circuitry 364 is connected to the first plurality of bonding pads 372A. For example, the pad configuration circuitry 364 is communicatively coupled to the first plurality of bonding pads 372A with multiple conductive paths 384, such as multiple communication paths. To illustrate, each node of the first set of nodes 365 of the pad configuration circuitry 364 is communicatively coupled to a corresponding bonding pad of the first plurality of bonding pads 372A via a respective conductive path of the multiple conductive paths 384.

The control circuitry 368 is configured to obtain the routing configuration 140. The routing configuration 140 may indicate a configuration of the pad configuration circuitry 364 to connect a portion of the first set of nodes 365 and the second set of nodes 367 to selectively connect the multiple nodes 363 of the second circuitry 362 to the set of bonding pads of the first plurality of bonding pads 372A. Additionally, or alternatively, the routing configuration 140 may indicate the set of bonding pads of the first plurality of bonding pads 372A, and for each node of the multiple nodes 363, a corresponding bonding pad of the set of bonding pads.

To obtain the routing configuration 140, the control circuitry 368 may perform a test operation with (e.g., between) the first die 110 that is coupled to the second die 360. The test operation may be configured to identify one or more defective bonding pads of the first plurality of bonding pads 122A, one or more defective conductive paths of the conductive paths 134, identify one or more defective bonding pads of the first plurality of bonding pads 372A, one or more defective conductive paths of the conductive paths 384, or a combination thereof. For example, the test operation may be initiated by the control circuitry 368 of the second die 360 or by the control circuitry 118 of the first die 110. In some implementations, the test operation is initiated based on power-up of the first die 110, power-up of the second die 360, expiration of a time period (e.g., a number of operational clock cycles of the second die 360, a number of operation clock cycles of the first die 110, hourly, daily, weekly, or at another specified time period), detection of a failure of a conductive path between the first die 110 and the second die 360, or a combination thereof.

To perform the test operation, the control circuitry 368 may receive a control signal from the control circuitry 118 to perform the test operation. In response to the control signal, the control circuitry 368 may configure the pad configuration circuitry 364 for the test operation in which signals (e.g., test signals) are provided from the pad configuration circuitry 364 to the first die 110 via the conductive paths 384. The pad configuration circuitry 114 (e.g., the detector circuitry 116) of the first die 110 may generate test data based on whether one or more signals provided by the pad configuration circuitry 364 are received via the first set of nodes 115. The test data may indicate whether or not one or more conductive paths and/or bonding pads are defective or available for use. For example, the test data may indicate a defectiveness (e.g., unviability) or availability of one or more conductive paths 134 or 384, one or more bonding pads of the first plurality of bonding pads 122A or 372A, or a combination thereof.

The control circuitry 368 may obtain the routing configuration 140 based on the test operation. For example, the control circuitry 118 may generate the routing configuration 140 based on the test data and send the routing configuration 140 to the second die 360 (e.g., the control circuitry 368 or the pad configuration circuitry 364). As another example, the control circuitry 118 may send the test data to the second die 360 (e.g., the control circuitry 368) and the second die 360 (e.g., the control circuitry 368) may generate the routing configuration 140. For example, the control circuitry 368 may generate the routing configuration 140 based on a mapping table, one or more routing constraints associated with the multiple nodes 363, or a combination thereof. As another example, the control circuitry 368 may provide the test data to an ML model that is trained to generate the routing configuration 140. In some implementations, the routing configuration 140 is generated to optimize signal routing, such as by determining shortest path routings. In some implementations where the routing configuration 140 is generated at the second die 360, the control circuitry 368 may send the routing configuration to the first die 110 (e.g., the control circuitry 118 or the pad configuration circuitry 114).

Although the first die 110 is described as including the detector circuitry 116 that is configured to generate the test data and the second die 360 is described as sending the test signals to the first die 110, in other implementations, the first die 110 may provide the test signals to the second die 360 and the second die 360 may include detector circuitry (such as the detector circuitry 116) to generate the test data. Additionally, or alternatively, it is noted that the detector circuitry 116 may be configured to generate the test signals that are provided to another die.

The pad configuration circuitry 364 is configured to connect the multiple nodes 363 of the second circuitry 362 to a set of bonding pads of the first plurality of bonding pads 372A. For example, pad configuration circuitry 364 configured to connect the multiple nodes 363 of the second circuitry 362 to the set of bonding pads of the first plurality of bonding pads 372A based on the routing configuration 140. To illustrate, the pad configuration circuitry 364 may configure one or more connections, within the pad configuration circuitry 364, between a portion of the first set of nodes 365 and the second set of nodes 367 to selectively connect the multiple nodes 363 of the second circuitry 362 to the set of bonding pads of the first plurality of bonding pads 372A. To configure the one or more connections, the pad configuration circuitry 114 may include one or more switches or circuits, such as an array of switches, gates, multiplexers, other components, the like, or a combination thereof. In some implementations, the pad configuration circuitry 364 is reconfigurable to selectively connect the multiple nodes 363 of the second circuitry 362 to a first set of bonding pads of the first plurality of bonding pads 372A or a second set of bonding pads of the first plurality of bonding pads 372A, where the first set of bonding pads is different from the second set of bonding pads.

During operation of the device 300, the device 100 may be powered on and control logic between the first die 110 and the second die 360. For example, the first die 110 and the second die 360 may synchronize communication between the control circuitry 118 of the first die 110 and the control circuitry 368 of the second die 360. To illustrate, the first die 110 and the second die 360 may synchronize communication via the conductive path 136, the second plurality of bonding pads 122B, the second plurality of bonding pads 372B, the conductive path 386, or a combination thereof.

After synchronization of communication between the first die 110 and the second die 360, the device 100 may perform a test operation to identify whether one or more signal paths between the first die 110 and the second die 360 are defective or available for use. For example, the one or more signal paths may enable communication of one or more signals between the pad configuration circuitry 114 of the first die 110 and the pad configuration circuitry 364 of the second die 360. Additionally, or alternatively, the one or more signal paths may include the conductive paths 134, the first plurality of bonding pads 122A, the first plurality of bonding pads 372A, the conductive paths 384, or a combination thereof. In some implementations, the device 300 may perform the test operation using the control circuitry 118, the detector circuitry 116, the pad configuration circuitry 114, the control circuitry 368, detector circuitry of the second die 360, the pad configuration circuitry 364, or a combination thereof.

The device 300 may, based on a result (e.g., test data) of the test operation, determine the routing configuration 140. For example, the routing configuration 140 may be determined by the control circuitry 118, the control circuitry 368, or a combination thereof. To illustrate, the control circuitry 118 or 368 may use a mapping logic table to determine the routing configuration 140 such that signal paths from or between the multiple nodes 113 and/or the multiple nodes 363 are a shortest path.

The device 300 may, based on the routing configuration 140, configure the pad configuration circuitry 114, the pad configuration circuitry 364, or a combination thereof. After configuring the pad configuration circuitry 114, the pad configuration circuitry 364, or a combination thereof, the device 300 may communicate signals between the first die 110 and the second die 360 via the configured pad configuration circuitry 114 and the configured pad configuration circuitry 364.

In some implementations, the device 300 may initiate another test operation. For example, the device 300 may initiate the other test operation based on power up of the device 300, power-up of the die 110, power-up of the second die 360, expiration of a time period (e.g., a number of operational clock cycles, daily, weekly, or other specified time period), detection of a failure of a conductive path between the die and the other die, or a combination thereof.

It should be understood that the device 300 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein. In some implementations, the device 300 may include an additional die (e.g., a third die) coupled to the first die 110 or the second die 360. To illustrate, the first die 110 or the second die 360 may be communicatively coupled to the third die.

In some implementations, the device 300 can be integrated in a portable communication device, such as a smartphone, a tablet computer, a fixed location terminal device, an automobile, a wearable electronic device, a laptop computer, or some combination thereof, as described in more detail below with reference to FIG. 12. While FIG. 3 illustrates an example device 300 that is a single device, the device 300 of FIG. 3 can be integrated with or included within a wide variety of other devices. For example, a device that includes the first die 110 and the second die 360 disclosed herein can include components such as a PMIC, an application processor, a modem, an RF device, a passive device, a filter, a capacitor, an inductor, a transmitter, a receiver, a GaAs based integrated device, an SAW filter, a BAW filter, an LED integrated device, an Si based integrated device, an SiC based integrated device, a memory, power management processor, and/or combinations thereof. In such devices, the first die 110 or the second die 360 can operate as any of these components (or a combination of these components) that includes active circuitry.

The device 300 thus provides (re) configurable routing of conductive paths between nodes and bonding pads of at least one die of the device as compared to other conventional dies that utilize redundant bonding pads in parallel. The configurable bonding pad routing provides routing flexibility to compensate for one or more defects from a Cu-to-Cu hybrid bonding process or one or more bonding pad failures during operation of the device. Accordingly, the first die 110 and the second die 360 can dynamically reconfigure the bonding pad routing, which may result in a life of the die being extended as compared to a conventional die that implements conventional redundant bonding pads in parallel. Additionally, or alternatively, the configurable bonding pad routing enables the device 300 to have fewer bonding pads as compared to a conventional die that implements conventional redundant bonding pads in parallel. Having fewer bonding pads as compared to the die that implements conventional redundant bonding pads in parallel can reduce design interconnect routing complexity, an amount of materials, a size, and a cost of the device. Additionally, or alternatively, the configurable bonding pad routing enables the device 300 to optimize signal routing to bonding pads and dynamically select short paths rather than being limited to a fixed path allocation as with the conventional die that that implements conventional redundant bonding pads in parallel.

In a particular implementation, the device 300 includes a stack of dies. The stack of dies includes a first die (e.g., the first die 110) and a second die (e.g., the second die 360) communicatively coupled to the first die (e.g., the first die 110). The first die (e.g., the first die 110) includes first circuitry (e.g., the first circuitry 112) including first multiple nodes (e.g., the multiple nodes 113). The first die (e.g., the first die 110) also includes multiple bonding pads (e.g., the multiple bonding pads 122) including a first plurality of bonding pads (e.g., the first plurality of bonding pads 122A). The first die (e.g., the first die 110) further includes first pad configuration circuitry (e.g., the pad configuration circuitry 114) configured to selectively connect the first multiple nodes (e.g., the multiple nodes 113) of the first circuitry (e.g., the first circuitry 112) to a first set of bonding pads of the first plurality of bonding pads (e.g., the first plurality of bonding pads 122A) of the first die (e.g., the first die 110). The second die (e.g., the second die 360) includes second circuitry (e.g., the second circuitry 362) including second multiple nodes (e.g., the multiple nodes 363). The second die (e.g., the second die 360) also includes multiple bonding pads (e.g., the multiple bonding pads 372) including a second plurality of bonding pads (e.g., the first plurality of bonding pads 372A). The second die (e.g., the second die 360) further includes second pad configuration circuitry (e.g., the pad configuration circuitry 364) configured to selectively connect the second multiple nodes (e.g., the multiple nodes 363) of the second circuitry (e.g., the second circuitry 362) to a first set of bonding pads of the second plurality of bonding pads (e.g., the first plurality of bonding pads 372A) of the second die (e.g., the second die 360).

In a particular implementation, a method of operation of a stack of dies includes obtaining a first routing configuration (e.g., the routing configuration 140) associated with first multiple nodes (e.g., the multiple nodes 113) of first circuitry (e.g., the first circuitry 112) of a first die (e.g., the first die 110) and a first plurality of bonding pads (e.g., the first plurality of bonding pads 122A) of the first die (e.g., the first die 110). The first die (e.g., the first die 110) is communicatively coupled to a second die (e.g., the second die 360). The method also includes selectively connecting, based on the first routing configuration (e.g., the routing configuration 140), the first multiple nodes (e.g., the multiple nodes 113) of the first circuitry (e.g., the first circuitry 112) to a first set of bonding pads of the first plurality of bonding pads (e.g., the first plurality of bonding pads 122A) of the first die (e.g., the first die 110).

Referring to FIG. 4, FIG. 4 illustrates an example of a device that includes configurable bonding pad routing. For example, FIG. 4 illustrates a device 400, an illustrative example 430 of the detector circuitry 116, and a logic table 450 associated with the detector circuitry 116.

The device 400 includes or corresponds to the device 300. The device 200 includes many of the same components and features as are described above with reference to FIGS. 1-3. Such components and features are physically and operationally the same as described above with reference to FIGS. 1-3 and are labeled in FIG. 4 using the same reference numbers. In some implementations, the device 400 includes all of the same features and components as the device 300 of FIG. 3; however, some components and features illustrated in FIG. 3 have been omitted from (or are not labeled with reference numbers in) FIG. 4 for simplicity of illustration. Omission of such features and reference numbers should not be understood as limiting the features and components of FIG. 4.

The device 400 includes multiple conductive paths 402 between the pad configuration circuitry 114 and the pad configuration circuitry 364. The multiple conductive paths 402 include the conductive paths 134 and 384 and the first plurality of bonding pads 122A and 372A. Each of the conductive paths 402 are configured to enable communication of one or more signals between the pad configuration circuitry 114 and the pad configuration circuitry 364. For example, each of the conductive paths 402 are configured to enable communication of one or more test signals between the pad configuration circuitry 114 and the pad configuration circuitry 364 during a test operation.

Referring to the illustrative example 430 of the detector circuitry 116, the detector circuitry 116 includes one or more inputs, such as a first input BL1, a second input BL2, and a third input BL3. Each of one or more inputs are configured to be coupled to a conductive path (of the conductive paths 402). For example, the first input BL1 may be coupled to a first conductive path, the second input BL2 may be coupled to a second conductive path, and the third input BL3 may be coupled to a third conductive path.

The detector circuitry 116 also includes one or more logic gates. For example, the one or more logic gates may include an and (AND) gate and multiple exclusive or (EXOR) gates. The detector circuitry 116 also includes a set of outputs. For example, the set of outputs may include a first output X, a second output Y, a third output Z, and a fourth output W.

The detector circuitry 116 is configured to be coupled to a first set of the conductive paths (of the conductive paths 402). To illustrate, the first input BL1 may be coupled to a conductive path that includes a first bonding pad BP1, the second input BL2 may be coupled to a conductive path that includes a second bonding pad BP2, and the third input BL3 may be coupled to a third bonding pad BP3. While the detector circuitry 116 is coupled to the first set of the conductive paths 402, the detector circuitry 116 may receive one or more test signals and generate output, via the set of outputs, output values based on the received one or more test signal. The output values may be used to determine whether each conductive path of the first set of conductive paths is defective or available for use. For example, referring to the logic table 450, the logic table may be used to determine whether each conductive path of the first set of conductive paths is defective or available for use.

Referring back to the detector circuitry 116, after making one or more determinations with respect to the first set of conductive paths, the detector circuitry 116 (e.g., the one or more inputs) may be coupled to a second set of conductive paths (of the conductive paths 402). The detector circuitry 116 may receive one or more test signals and determine whether each conductive path of the second set of conductive paths is defective or available for use.

It is noted that the detector circuitry 116 and the logic table 450 are provided as illustrative examples. For example, the detector circuitry may include a different number of inputs, a different number of outputs, a different number, type or configuration of logic gates, or a combination thereof. Accordingly, the detector circuitry 116 and the logic table 450 described with reference to FIG. 4 are not intended to be limiting and other configurations or implementation of the detector circuitry 116 and the logic table 450 are possible.

Referring to FIG. 5, FIG. 5 illustrates examples of different routing configurations of a device having configurable bonding pad routing. For example, the device may include or correspond to the device 100 or 300.

The device of FIG. 5 includes many of the same components and features as are described above with reference to FIGS. 1-3. Such components and features are physically and operationally the same as described above with reference to the first die 110 of FIGS. 1-3 and are labeled in FIG. 5 using the same reference numbers. In some implementations, the device of FIG. 5 includes all of the same features and components as the first die 110 of FIGS. 1-3; however, some components and features illustrated in FIGS. 1-3 have been omitted from (or are not labeled with reference numbers in) FIG. 5 for simplicity of illustration. Omission of such features and reference numbers should not be understood as limiting the features and components of FIG. 5 to only those specifically called out below.

The examples of different routing configurations of the device of FIG. 5 include a first example 500 of a first routing configuration of the first die 110 and a second example 550 of a second routing configuration of the first die 110. Each of the first routing configuration and the second routing configuration may include or correspond to the routing configuration 140. It is noted that the first die 110 may be communicatively coupled with the second die 360, as described with reference to FIG. 3.

In the examples 500 and 550, the numerical values included in the first set of nodes 115 and the second set of nodes 117 indicate that nodes having the same number are communicatively coupled by the pad configuration circuitry 114. As an illustrative example, referring to the first example 500, a dashed line represents a connection between a bonding pad (including the number 1) of the first set of nodes 115 and a bonding pad (including the number 1) of the second set of nodes 117. Additionally, in the examples 500 and 550, the letter “X” included in a node of the first set of nodes 115 indicates that a defect has been detected that is associated with the node. For example, the defect may be associated with a communication path (e.g., the conductive paths 134 or 384) and/or a bonding pad (of the first plurality of bonding pads 122A or 372A).

Referring to the first example 500, the pad configuration circuitry 114 is configured in a first configuration based on the first routing configuration. For example, the pad configuration circuitry 114 may be configured to connect the nodes 117 to a first set of nodes of the nodes 115 (e.g., a first set of bonding pads of the first plurality of bonding pads 122A). In the first configuration, a node 115A is connected to one of the nodes 117 as indicated by the number 5, a node 115B is connected to one of the nodes 117 as indicated by the number 8, and a node 115C is connected to one of the nodes 117 as indicated by the number 9. Additionally, a node 115D is not connected to the nodes 117 as indicated by no value being included in the node 115D. Further, it is noted that the node 115E is associated with a defect (e.g., of a communication/signal path between the pad configuration circuitry 114 and the pad configuration circuitry 364) as indicated by the letter X.

After being configured based on the first configuration, the device may perform a test operation to generate test data. For example, the test data may indicate that a connection path associated with the node 115B is defective. Based on the test data, the device may obtain the second routing configuration and configure the pad configuration circuitry 114 based on the second routing configuration.

Referring to the second example 550, the pad configuration circuitry 114 is configured in a second configuration based on the second routing configuration. For example, the pad configuration circuitry 114 may be configured to connect the nodes 117 to a second set of nodes of the nodes 115 (e.g., a second set of bonding pads of the first plurality of bonding pads 122A). To illustrate, in the second configuration, the node 115A is connected to one of the nodes 117 as indicated by the number 5, the node 115C is connected to one of the nodes 117 as indicated by the number 8, and a node 115D is connected to one of the nodes 117 as indicated by the number 9. Additionally, it is noted that each of the node 115E and the node 115B are associated with a defect (e.g., of a communication/signal path between the pad configuration circuitry 114 and the pad configuration circuitry 364) as indicated by the letter X.

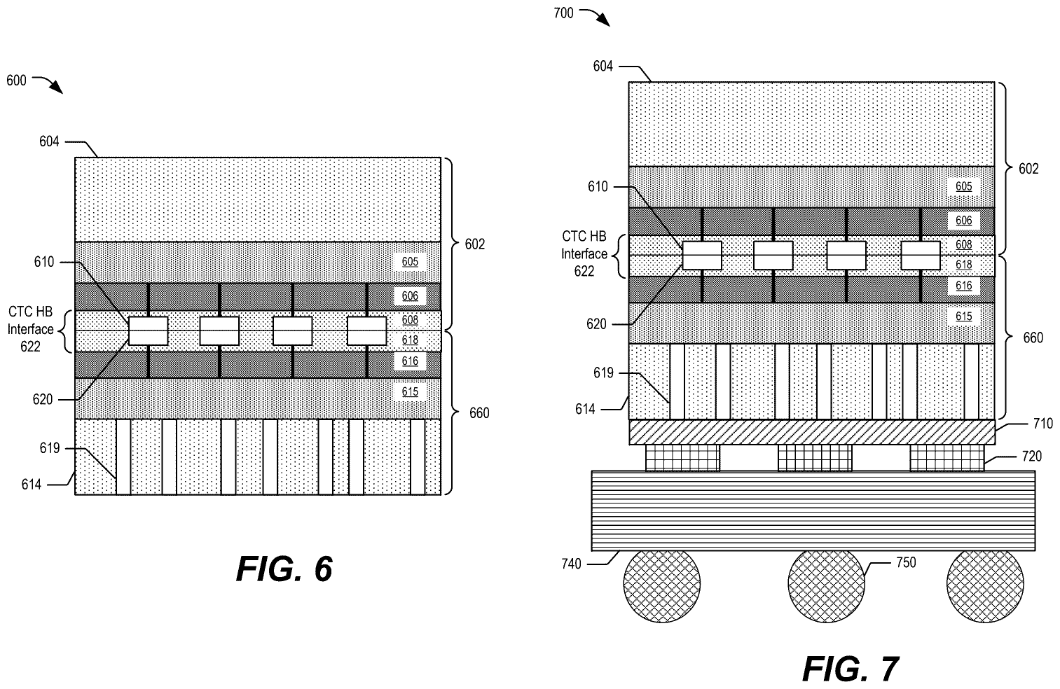

FIG. 6 illustrates a cross-sectional profile view of a particular implementation of a device 600 that includes configurable bonding pad routing. For example, the device may include or correspond to the device 300.

The device 600 may include many of the same components and features as are described above with reference to FIG. 1-5. Such components and features may be physically and operationally the same as described above with reference to FIGS. 1-5. In some implementations, the device 600 includes all of the same features and components as the device 300.

The device 600 includes a first die 602 and a second die 660. The first die 602 may include or correspond to the first die 110. The second die 660 may include or correspond to the second die 360. The first die 602 is coupled to the second die 660. To illustrate, the device 600 may include a CTC HB interface 622 that coupled the first die 602 and the second die 660 together. The CTC HB interface 622 may include or correspond to the CTC HB interface 302.

The first die 602 may include a substrate layer 604 (e.g., a silicon layer), a FEOL layer 605, a BEOL layer 606, and a back BEOL (BBEOL) layer 608. In some implementations, the BBEOL layer 608 includes or corresponds to the oxide layer 120. The first die 602 may also include a first plurality of bonding pads 610. The first plurality of bonding pads 610 include or correspond to the first plurality of bonding pads 122A of the first die 110. In some implementations, the first die 602 includes pad configuration circuitry, such as the pad configuration circuitry 114. Additionally, or alternatively, the first die 602 may include control circuitry (e.g., the control circuitry 118), detector circuitry (e.g., the detector circuitry 116), first circuitry (e.g., the first circuitry 112), or a combination thereof.

The second die 660 may include a substrate layer 614, a FEOL layer 615, a BEOL layer 616, and a BBEOL layer 618. In some implementations, the BBEOL layer 618 may include or correspond to the oxide layer 370. The second die 660 may also include a second plurality of bonding pads 620. The second plurality of bonding pads 620 include or correspond to the first plurality of bonding pads 372A of the second die 360. In some implementations, the second die 660 includes pad configuration circuitry, such as the pad configuration circuitry 364. Additionally, or alternatively, the second die 660 may include control circuitry (e.g., the control circuitry 368), detector circuitry, second circuitry (e.g., the second circuitry 362), or a combination thereof.

In some implementations, the substrate layer 614 of the second die 660 includes one or more through-silicon vias (TSVs) 619. Although the TSVs 619 are described as being included in the substrate layer 614 of the second die 660, in other implementations, the substrate layer 604 of the first die 602 may additionally or alternatively include one or more TSVs.

FIG. 7 illustrates a cross-sectional profile view of a particular implementation of a device 700 that includes configurable bonding pad routing. For example, the device 700 may include or correspond to the device 300 or the device 600.

The device 700 may include many of the same components and features as are described above with reference to FIGS. 1-6. Such components and features may be physically and operationally the same as described above with reference to FIGS. 1-6. In some implementations, the device 700 includes all of the same features and components as the device 300 or 600.

The device 600 includes the first die 602, the second die 660, and a third die 740. An interconnect layer 710 is coupled to the second die 660. In some implementations, the second die 660 includes the interconnect layer 710. The second die 660 may be coupled, such as communicatively or electrically coupled, to the third die 740 via the interconnect layer 710 and a set of connectors 720. The third die 740 may also be coupled to or include a set of connectors 750, such as a set of solder bumps.

### Exemplary Sequence for Fabricating a Device/IC Device Including Configurable Bonding Pad Routing

In some implementations, fabricating a device, such as a stack of dies, including configurable bonding pad routing (e.g., the device 300, 600, or 700) includes several processes. FIG. 8 illustrates an exemplary sequence for fabricating or providing a device that includes configurable bonding pad routing, as described with reference to any of FIGS. 1-7. In some implementations, the sequence of FIG. 8 may be used to provide (e.g., during fabrication of) the device 300, 600, or 700.

It should be noted that the sequence of FIG. 8 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 8. Each of the various stages of the sequence illustrated in FIG. 8 shows formation of a stack of dies, such as formation of a stack of dies using a CTC HB process.

Stage 1 of FIG. 8 illustrates a state after dies are obtained. For example, as part of Stage 1, a first die 802 and a second die 812 may be obtained. The first die 802 may include or correspond to the first die 110, the die 602 or 660, or a combination thereof. In some implementations, the first die 802 includes pad configuration circuitry, such as the pad configuration circuitry 114. Additionally, or alternatively, the first die 802 may include control circuitry (e.g., the control circuitry 118), detector circuitry (e.g., the detector circuitry 116), first circuitry (e.g., the first circuitry 112), or a combination thereof. The second die 812 may include or correspond to the second die 360, the die 602 or 660, or a combination thereof. In some implementations, the second die 812 includes pad configuration circuitry, such as the pad configuration circuitry 364. Additionally, or alternatively, the second die 812 may include control circuitry (e.g., the control circuitry 368), detector circuitry, second circuitry (e.g., the second circuitry 362), or a combination thereof.

The first die 802 may include a substrate layer 804 (e.g., a silicon layer), a BEOL layer 806, and a BBEOL layer 808. The substrate layer 804 may include or correspond to the substrate layer 604. The BEOL layer 806 may include or correspond to the BEOL layer 606. In some implementations, the BBEOL layer 808 may include or correspond to the oxide layer 120 or the BBEOL layer 608. The first die 802 may also include a first plurality of bonding pads 810. The first plurality of bonding pads 810 include or correspond to the first plurality of bonding pads 122A of the first die 110.

The second die 812 may include a substrate layer 814, a BEOL layer 816, and a BBEOL layer 818. The substrate layer 814 may include or correspond to the substrate layer 614. The BEOL layer 816 may include or correspond to the BEOL layer 616. In some implementations, the BBEOL layer 818 may include or correspond to the oxide layer 370. The second die 812 may also include a second plurality of bonding pads 820. The second plurality of bonding pads 820 include or correspond to the first plurality of bonding pads 372A of the second die 360.

Stage 2 illustrates a state after the first die 802 and the second die 812 are positioned in contact for a CTC HB operation. Stage 3 illustrates a state of a device 830 after formation of a CTC HB interface 822 based on the CTC HB operation. The CTC HB interface 822 may include or correspond to the CTC HB interface 302. As part of the CTC HB operation, oxide-to-oxide bonding may occur between an oxide of the BBEOL layer 808 and an oxide of the BBEOL layer 818. Additionally, as part of the CTC HB operation, CTC thermal compression bonding may occur between one or more bonding pads of the first plurality of bonding pads 810 and the second plurality of bonding pads 820.

In some implementations, the CTC HB operation may result in a defectivity associated with one or more bonding pads of the first plurality of bonding pads 810 and/or the second plurality of bonding pads 820. For example, a defectivity may occur based on or as a result of a process stability and/or complexity of the CTC HB operation, a foreign material in a fabrication environment in which the CTC HB operation is performed, another factor, or a combination thereof. As an illustrative example of a defectivity, a defect 832 may be formed in the device 830 as indicated by an “X”

Formation of the device 830 (e.g., a device including configurable bonding pad routing) is complete after Stage 3 of FIG. 8. Although certain Stages are illustrated in FIG. 8 in forming the device 830, other processes can be included in the fabrication of the device 830 without departing from the scope of the subject disclosure. For example, fabricating the device 830 can include fabricating the first die 802. As another example, fabricating the device 830 can include fabricating the second die 812. Additionally, or alternatively, fabricating the device 830 can include fabricating the first die 802, fabricating the second die 812, or a combination thereof. Additionally, or alternatively, fabricating the device 830 can include, after Stage 3 of FIG. 8, configuring bonding pad routing of the device 830.

### Exemplary Flow Diagram of a Method for Fabricating a Device/Integrated Device Including Configurable Bonding Pad Routing

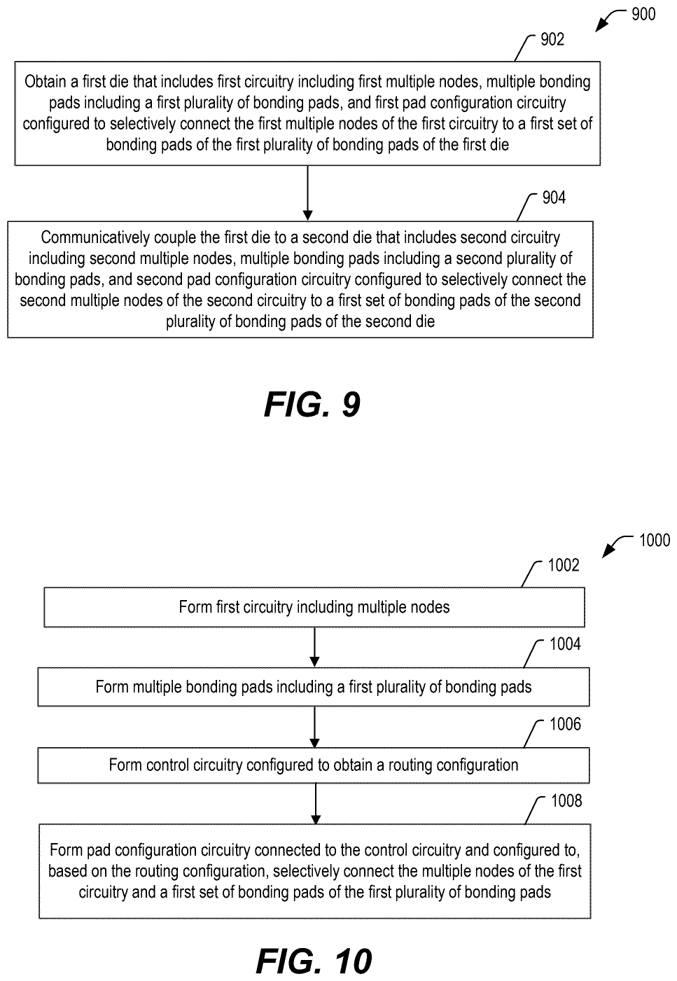

In some implementations, fabricating a device including configurable bonding pad routing includes several processes. FIG. 9 illustrates an exemplary flow diagram of a method 900 of fabricating an illustrative device that includes configurable bonding pad routing. In a particular aspect, one or more operations of the method 900 are performed by one or more processors of a fabrication system. In some implementations, operations of the method 900 may be stored as instructions by a non-transitory computer-readable storage medium, and the instructions may be executable by at least one processor to cause the at least one processor to perform operations of the method 900. In some implementations, the method 900 of FIG. 9 may be used to provide or fabricate the device 300, 600, or 700. For example, the method 900 may be used to fabricate a stack of dies.

It should be noted that the method 900 of FIG. 9 may combine one or more processes in order to simplify and/or clarify the method for providing or fabricating an integrated circuit device. In some implementations, the order of the processes may be changed or modified.

The method 900 includes, at block 902, obtaining a first die. For example, Stage 1 of FIG. 8 illustrates and describes examples of obtaining the first die. The first die may include or correspond to the die 110, 602, or 802. The first die includes first circuitry 112 including first multiple nodes. For example, the first circuitry and the first multiple nodes include or correspond to the first circuitry 112 and the multiple nodes 113, respectively. The first die also includes multiple bonding pads including a first plurality of bonding pads. The multiple bonding pads and the first plurality of bonding pads of the first die include or correspond to the multiple bonding pads 122 and the first plurality of bonding pads 122A, respectively. The first die also includes first pad configuration circuitry configured to selectively connect the first multiple nodes of the first circuitry to a first set of bonding pads of the first plurality of bonding pads of the first die. The first pad configuration circuitry includes or corresponds to the pad configuration circuitry 114.

In some implementations, the first die 110 further includes first control circuitry connected to the first pad configuration circuitry. For example, the first control circuitry may include or correspond to the control circuitry 118. The first control circuitry is configured to obtain a routing configuration, such as the routing configuration 140. Additionally, or alternatively, the first pad configuration circuitry is configured to selectively connect the first multiple nodes of the first circuitry to the first set of bonding pads of the first plurality of bonding pads of the first die based on the routing configuration.

At block 904, the method 900 includes communicatively coupling the first die to a second die. For example, Stage 2 of FIG. 8 illustrates and describes examples of communicatively coupling the first die to the second die. The second die may include or correspond to the second die 360, 660, or 812. The second die includes second circuitry including second multiple nodes. The second circuitry and the second multiple nodes may include or correspond to the second circuitry 362 and the multiple nodes 363. The second die also includes multiple bonding pads including a second plurality of bonding pads. The multiple bonding pads and the second plurality of bonding pads of the second die include or correspond to the multiple bonding pads 372 and the second plurality of bonding pads 372A. The second die further includes second pad configuration circuitry configured to selectively connect the second multiple nodes of the second circuitry to a first set of bonding pads of the second plurality of bonding pads of the second die. For example, the second pad configuration circuitry may include or correspond to the pad configuration circuitry 364.

In some implementations, the second die 360 further includes second control circuitry connected to the second pad configuration circuitry. The second control circuitry may include or correspond to the control circuitry 368. The second control circuitry is configured to receive a routing configuration from first control circuitry of the first die. The routing configuration and the first control circuitry include or correspond to the routing configuration 140 and the control circuitry 118, respectively. Additionally, or alternatively, the second pad configuration circuitry is configured to selectively connect the second multiple nodes of the second circuitry to the first set of bonding pads of the second plurality of bonding pads of the second die based on the routing configuration.

In some implementations, the method 900 also includes forming a die, such as the first die or the second die. An example of forming the die is described further herein at least with reference to FIG. 10.

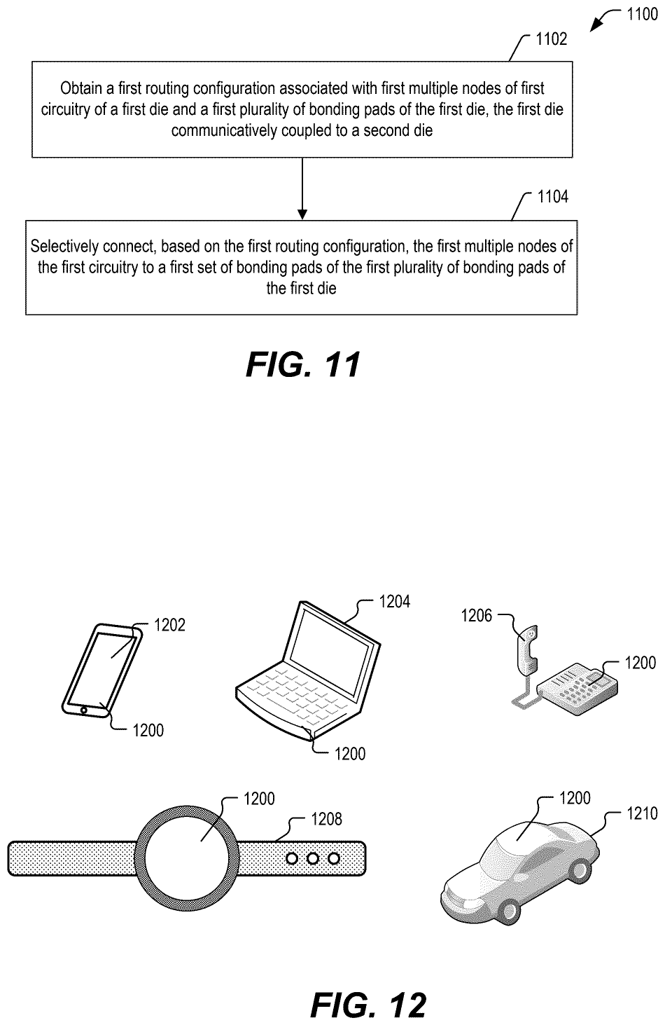

Referring to FIG. 10, FIG. 10 illustrates an exemplary flow diagram of a method 1000 of fabricating an illustrative device that includes configurable bonding pad routing. In a particular aspect, one or more operations of the method 1000 are performed by one or more processors of a fabrication system. In some implementations, operations of the method 1000 may be stored as instructions by a non-transitory computer-readable storage medium, and the instructions may be executable by at least one processor to cause the at least one processor to perform operations of the method 1000. In some implementations, the method 1000 of FIG. 11 may be used to provide or fabricate a device, such as the device 100, the first die 110, the device 300, the second die 360, the device 600, the die 602 or 660, or the device 700.

It should be noted that the method 1000 of FIG. 10 may combine one or more processes in order to simplify and/or clarify the method for providing or fabricating an integrated circuit device. In some implementations, the order of the processes may be changed or modified.

The method 1000 includes, at block 1002, forming first circuitry including multiple nodes. For example, the first circuitry may include or correspond to the first circuitry 112 or the second circuitry 362. The multiple nodes may include or correspond to the multiple nodes 113 or the multiple nodes 363.

At block 1004, the method 1000 includes forming multiple bonding pads including a first plurality of bonding pads. For example, the multiple bonding pads may include or correspond to the multiple bonding pads 122 or 372. The first plurality of bonding pads may include or correspond to the first plurality of bonding pads 122A or 372A.

At block 1006, the method 1000 includes forming control circuitry configured to obtain a routing configuration. For example, the control circuitry may include or correspond to the control circuitry 118 or 368. The routing configuration may include or correspond to the routing configuration 140.

At block 1008, the method 1000 includes forming pad configuration circuitry connected to the control circuitry and configured to, based on the routing configuration, selectively connect the multiple nodes of the first circuitry and a first set of bonding pads of the first plurality of bonding pads. For example, the pad configuration circuitry may include or correspond to the pad configuration circuitry 114 or 364.

In some implementations, the method 1000 also includes forming detector circuitry configured to generate test data that indicates one or more defective conductive paths, one or more available conductive paths, or a combination thereof. For example, the detector circuitry may include or correspond to the detector circuitry 116. Additionally, or alternatively, the method 1000 may also include forming multiple conductive paths conductively coupled to the pad configuration circuitry and the first plurality of bonding pads. The multiple conductive paths may include or correspond to the conductive paths 134 or 384.

### Exemplary Flow Diagram of a Method for Fabricating a Device/Integrated Device Including Configurable Bonding Pad Routing

In some implementations, operating a device including configurable bonding pad routing includes one or more processes. FIG. 11 illustrates an exemplary flow diagram of a method 1100 of operating an illustrative device that includes configurable bonding pad routing. In some implementations, the device may include a stack of dies. Additionally, or alternatively, the method 1100 of FIG. 11 may be performed by or to operate a device, such as the device 100, the first die 110, the device 300, the second die 360, the device 600, the die 602 or 660, or the device 700.

It should be noted that the method 1100 of FIG. 11 may combine one or more processes in order to simplify and/or clarify the method for operating an integrated circuit device. In some implementations, the order of the processes may be changed or modified.

The method 1100, at block 1102, includes obtaining a first routing configuration associated with first multiple nodes of first circuitry of a first die and a first plurality of bonding pads of the first die. For example, the first die may include or correspond to the first die 110, the die 602 or 660, or the first die 802. The first multiple nodes of the first circuitry may include or correspond to the multiple nodes 113 of the first circuitry 112. The first plurality of bonding pads of the first die may include or correspond to the first plurality of bonding pads 122A. The first routing configuration may include or correspond to the routing configuration 140. The first die is communicatively coupled to a second die. For example, the second die may include or correspond to the second die 360, the die 602 or 660, or the second die 812.

In some implementations, the first routing configuration indicates a configuration of first pad configuration circuitry of the first die, second pad configuration circuitry of the second die, or a combination thereof. For example, the first pad configuration circuitry of the first die may include or correspond to the pad configuration circuitry 114. As another example, the second pad configuration circuitry of the second die may include or correspond to the pad configuration circuitry 364.

At block 1104, the method 1100 includes selectively connecting, based on the first routing configuration, the first multiple nodes of the first circuitry to a first set of bonding pads of the first plurality of bonding pads of the first die. The first set of bonding bads of the first plurality of bonding pads of the first die may include a portion and not an entirety of the first plurality of bonding pads of the first die. In some implementations, selectively connecting the multiple nodes of the first circuitry and the first set of bonding pads of the plurality of bonding pads includes configuring the first pad configuration circuitry of the first die.

In some implementations, the method 1100 also includes communicating between first control circuitry of the first die and second control circuitry of the second die to synchronize communication between the first die and the second die. For example, the first control circuitry of the first die may include or correspond to the control circuitry 118 of the first die 110. The second control circuitry of the second die may include or correspond to the control circuitry 368 of the second die 360.

In some implementations, the method 1100 also includes performing a test operation between the first die and the second die. The test operation may be performed based on power-up of the first die, power-up of the second die, expiration of a time period, detection of a failure of a communication path (e.g., the conductive paths 134 and/or 384), or a combination thereof. To perform the test operation, the method 1100 may include providing a first signal via a first conductive path between the first die and the second die. For example, the first conductive path may include or correspond to a conductive path of the conductive paths 134 and/or 348. Additionally, or alternatively, the method 1100 may include indicating whether the first conductive path is defective or available for use. To illustrate, the first conductive path may be determined to be defective or available for use based on the first signal provided via the first conductive path. In some implementations, the method 1100 may obtain the first routing configuration by determining the first routing configuration based on the first conductive path being defective or available for use.

In some implementations, the method 1100 includes obtaining a second routing configuration associated with the first multiple nodes of the first circuitry and the first plurality of bonding pads. For example, the second routing configuration may include or correspond to the routing configuration 140. Based on the second routing configuration, the method 1100 may include selectively connecting the first multiple nodes of the first circuitry to a second set of bonding pads of the first plurality of bonding pads. The second set of bonding pads may be different from the first set of bonding pads. For example, the second set of bonding pads may include at least one bonding pad that is not included in the first set of bonding pads. In some implementations, the method 1100 includes communicating one or more signals between the first die and the second die via the second set of bonding pads.

### Exemplary Electronic Devices

FIG. 12 illustrates various electronic devices that may include or be integrated with any of the device 100, 300, 600, or 700 (that includes configurable bonding pad routing). For example, a mobile phone device 1202, a laptop computer device 1204, a fixed location terminal device 1206, a wearable device 1208, or a vehicle 1210 (e.g., an automobile or an aerial device) may include a device 1200. The device 1200 can include, for example, any of the device 100, 300, 600, or 700, and/or any other integrated device that includes a conductive structure described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

It is noted that one or more blocks (or operations) described with reference to FIGS. 8-12 may be combined with one or more blocks (or operations) described with reference to another of the figures. For example, one or more blocks (or operations) of FIG. 9 may be combined with one or more blocks (or operations) of FIG. 11. As another example, one or more blocks associated with FIG. 10 may be combined with one or more blocks (or operations) of FIG. 9 or 11. As another example, one or more blocks associated with FIGS. 8-12 may be combined with one or more blocks (or operations) associated with FIGS. 1-7.

One or more of the components, processes, features, and/or functions illustrated in FIGS. 1-12 may be rearranged and/or combined into a single component, process, feature or function or embodied in several components, processes, or functions. Additional elements, components, processes, and/or functions may also be added without departing from the disclosure. It should also be noted FIGS. 1-12 and its corresponding description in the present disclosure is not limited to dies and/or ICs. In some implementations, FIGS. 1-12 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purposes of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling or electrical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third”, and “fourth” (and/or anything above fourth) is arbitrary. Any of the components described may be the first component, the second component, the third component or the fourth component. For example, a component that is referred to as a second component, may be the first component, the second component, the third component or the fourth component.

The terms “encapsulate”, “encapsulating”, or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component.

A value that is about X-XX, may mean a value that is between X and XX, inclusive of X and XX. The value(s) between X and XX may be discrete or continuous. The term “about ‘value X”, or “approximately value X”, as used in the disclosure means within 10 percent of the ‘value X’. For example, a value of about 1 or approximately 1, would mean a value in a range of 0.9-1.1. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a die, where the die includes: first circuitry including multiple nodes; multiple bonding pads including a first plurality of bonding pads; pad configuration circuitry configured to, based on a routing configuration, selectively connect the multiple nodes of the first circuitry to a first set of bonding pads of the first plurality of bonding pads; and control circuitry connected to the pad configuration circuitry, the control circuitry configured to obtain the routing configuration.

Example 2 includes the device of Example 1, where: a total number of bonding pads of the first plurality of bonding pads is less than three times a total number of nodes of the multiple nodes of the first circuitry; and the routing configuration indicates: the first set of bonding pads, and, for each node of the multiple nodes, a corresponding bonding pad of the first set of bonding pads.

Example 3 includes the device of Example 1 or Example 2, the device further includes multiple conductive paths conductively coupled to the pad configuration circuitry, and where: each conductive path of the multiple conductive paths corresponds to a different bonding pad of the first plurality of bonding pads, the multiple bonding pads include a second plurality of bonding pads coupled to the control circuitry, and the second plurality of bonding pads is configured to enable communication between the control circuitry of the die and control circuitry of a second die coupled to the die.

Example 4 includes the device of any of Examples 1 to 3, where the control circuitry is configured to communicate with second control circuitry of a second die to synchronize communication between the die and the second die; and initiate a test operation between the die and the second die, the test operation initiated based on power-up of the die, power-up of the second die, expiration of a time period, or on detection of a failure of a conductive path between the die and the second die.

Example 5 includes the device of any of Examples 1 to 4, where the control circuitry is configured to receive the routing configuration from second control circuitry of a second die coupled to the die.

Example 6 includes the device of any of Examples 1 to 4, where the die further includes detector circuitry configured to generate test data that indicates one or more defective conductive paths, one or more available conductive paths, or a combination thereof.

Example 7 includes the device of Example 6, where, to perform a test operation associated with at least one conductive path between the die and a second die, the detector circuitry is configured to receive, from the second die, a first signal via a first conductive path of the at least one conductive path, the first conductive path including a bonding pad of the first plurality of bonding pads; and generate test data that indicates whether the first conductive path is defective or available for use.

Example 8 includes the device of Example 7, where, to obtain the routing configuration, the control circuitry is configured to generate the routing configuration based on the test data, a mapping table, one or more routing constraints associated with the multiple nodes, or a combination thereof.

Example 9 includes the device of Example 7, where the control circuitry is configured to provide the test data to a machine learning (ML) model that is trained to generate the routing configuration.

Example 10 includes the device of any of Examples 1 to 9, where: the control circuitry is configured to identify a first defective conductive path associated with a first bonding pad included in the first set of bonding pads; and obtain a second routing configuration based on the identified first defective conductive path; and the pad configuration circuitry is configured to, based on the second routing configuration, selectively connect the multiple nodes of the first circuitry to a second set of bonding pads of the first plurality of bonding pads.

Example 11 includes the device of any of Examples 1 to 10, the device further includes a second die communicatively coupled to the die, where the second die includes: second circuitry including multiple nodes; a second plurality of bonding pads; second pad configuration circuitry configured to, based on the routing configuration, selectively connect the multiple nodes of the second circuitry to a first set of bonding pads of the second plurality of bonding pads of the second die; and second control circuitry connected to the second pad configuration circuitry, the second control circuitry configured to obtain the routing configuration.

Example 12 includes the device of Example 11, the device further includes a chip stack that includes: the die communicatively coupled to the second die; and a third die communicatively coupled to the die, and where the die is communicatively coupled to the second die based on a copper-to-copper hybrid bonding.

According to Example 13, a method of fabrication includes obtaining a first die that includes: first circuitry including first multiple nodes; multiple bonding pads including a first plurality of bonding pads; and first pad configuration circuitry configured to selectively connect the first multiple nodes of the first circuitry to a first set of bonding pads of the first plurality of bonding pads of the first die; and communicatively coupling the first die to a second die, where the second die includes: second circuitry including second multiple nodes; multiple bonding pads including a second plurality of bonding pads; and second pad configuration circuitry configured to selectively connect the second multiple nodes of the second circuitry to a first set of bonding pads of the second plurality of bonding pads of the second die.

Example 14 includes the method of Example 13, the method further includes forming the first die, where forming the first die includes: forming the first circuitry; forming the multiple bonding pads; and forming the pad configuration circuitry.

Example 15 includes the method of Example 14, where, forming the first die further includes: forming control circuitry connected to the pad configuration circuitry, the control circuitry configured to obtain the routing configuration.

According to Example 16, a method of operation of a stack of dies includes obtaining a first routing configuration associated with first multiple nodes of first circuitry of a first die and a first plurality of bonding pads of the first die, the first die communicatively coupled to a second die; and selectively connecting, based on the first routing configuration, the first multiple nodes of the first circuitry to a first set of bonding pads of the first plurality of bonding pads of the first die.

Example 17 includes the method of Example 16, where selectively connecting the multiple nodes of the first circuitry and the first set of bonding pads of the plurality of bonding pads includes configuring first pad configuration circuitry of the first die.

Example 18 includes the method of Example 16 or Example 17, the method further includes obtaining a second routing configuration associated with the first multiple nodes of the first circuitry and the first plurality of bonding pads; selectively connecting, based on the second routing configuration, the first multiple nodes of the first circuitry to a second set of bonding pads of the first plurality of bonding pads, the second set of bonding pads different from the first set of bonding pads; and communicating one or more signals between the first die and the second die via the second set of bonding pads.

Example 19 includes the method of any of Examples 16 to 18, the method further includes communicating between first control circuitry of the first die and second control circuitry of the second die to synchronize communication between the first die and the second die; and performing a test operation between the first die and the second die, where the test operation includes: providing a first signal via a first conductive path between the first die and the second die; and indicating whether the first conductive path is defective or available for use.

Example 20 includes the method of Example 19, where: obtaining the first routing configuration includes determining the first routing configuration based on the first conductive path being defective or available for use; and the first routing configuration indicates a configuration of first pad configuration circuitry of the first die, second pad configuration circuitry of the second die, or a combination thereof.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a die including:
first circuitry including multiple nodes;
multiple bonding pads including a first plurality of bonding pads;
pad configuration circuitry configured to, based on a routing configuration, selectively connect the multiple nodes of the first circuitry to a first set of bonding pads of the first plurality of bonding pads; and
control circuitry connected to the pad configuration circuitry, the control circuitry configured to obtain the routing configuration.

2. The device of claim 1, wherein:
a total number of bonding pads of the first plurality of bonding pads is less than three times a total number of nodes of the multiple nodes of the first circuitry; and
the routing configuration indicates:
the first set of bonding pads, and
for each node of the multiple nodes, a corresponding bonding pad of the first set of bonding pads.

3. The device of claim 1, further comprising:
multiple conductive paths conductively coupled to the pad configuration circuitry, and
wherein:
each conductive path of the multiple conductive paths corresponds to a different bonding pad of the first plurality of bonding pads,
the multiple bonding pads include a second plurality of bonding pads coupled to the control circuitry, and
the second plurality of bonding pads is configured to enable communication between the control circuitry of the die and control circuitry of a second die coupled to the die.

4. The device of claim 1, wherein the control circuitry is configured to:
communicate with second control circuitry of a second die to synchronize communication between the die and the second die; and
initiate a test operation between the die and the second die, the test operation initiated based on power-up of the die, power-up of the second die, expiration of a time period, or on detection of a failure of a conductive path between the die and the second die.

5. The device of claim 1, wherein the control circuitry is configured to receive the routing configuration from second control circuitry of a second die coupled to the die.

6. The device of claim 1, wherein the die further includes detector circuitry configured to generate test data that indicates one or more defective conductive paths, one or more available conductive paths, or a combination thereof.

7. The device of claim 6, wherein, to perform a test operation associated with at least one conductive path between the die and a second die, the detector circuitry is configured to:
receive, from the second die, a first signal via a first conductive path of the at least one conductive path, the first conductive path including a bonding pad of the first plurality of bonding pads; and
generate test data that indicates whether the first conductive path is defective or available for use.

8. The device of claim 7, wherein, to obtain the routing configuration, the control circuitry is configured to generate the routing configuration based on the test data, a mapping table, one or more routing constraints associated with the multiple nodes, or a combination thereof.

9. The device of claim 7, wherein the control circuitry is configured to provide the test data to a machine learning (ML) model that is trained to generate the routing configuration.

10. The device of claim 1, wherein:
the control circuitry is configured to:
identify a first defective conductive path associated with a first bonding pad included in the first set of bonding pads; and
obtain a second routing configuration based on the identified first defective conductive path; and
the pad configuration circuitry is configured to, based on the second routing configuration, selectively connect the multiple nodes of the first circuitry to a second set of bonding pads of the first plurality of bonding pads.

11. The device of claim 1, further comprising:
a second die communicatively coupled to the die, wherein the second die includes:
second circuitry including multiple nodes;
a second plurality of bonding pads;
second pad configuration circuitry configured to, based on the routing configuration, selectively connect the multiple nodes of the second circuitry to a first set of bonding pads of the second plurality of bonding pads of the second die; and
second control circuitry connected to the second pad configuration circuitry, the second control circuitry configured to obtain the routing configuration.

12. The device of claim 11, further comprising:
a chip stack that includes:
the die communicatively coupled to the second die; and
a third die communicatively coupled to the die, and
wherein the die is communicatively coupled to the second die based on a copper-to-copper hybrid bonding.

13. A method of fabrication, the method comprising:
obtaining a first die that includes:
first circuitry including first multiple nodes;
multiple bonding pads including a first plurality of bonding pads; and
first pad configuration circuitry configured to selectively connect the first multiple nodes of the first circuitry to a first set of bonding pads of the first plurality of bonding pads of the first die; and
communicatively coupling the first die to a second die, wherein the second die includes:
second circuitry including second multiple nodes;
multiple bonding pads including a second plurality of bonding pads; and
second pad configuration circuitry configured to selectively connect the second multiple nodes of the second circuitry to a first set of bonding pads of the second plurality of bonding pads of the second die.

14. The method of claim 13, further comprising:
forming the first die, wherein forming the first die includes:
forming the first circuitry;
forming the multiple bonding pads; and
forming the pad configuration circuitry.

15. The method of claim 14, wherein, forming the first die further includes:
forming control circuitry connected to the pad configuration circuitry, the control circuitry configured to obtain the routing configuration.

16. A method of operation of a stack of dies, the method comprising:
obtaining a first routing configuration associated with first multiple nodes of first circuitry of a first die and a first plurality of bonding pads of the first die, the first die communicatively coupled to a second die; and
selectively connecting, based on the first routing configuration, the first multiple nodes of the first circuitry to a first set of bonding pads of the first plurality of bonding pads of the first die.

17. The method of claim 16, wherein selectively connecting the multiple nodes of the first circuitry and the first set of bonding pads of the plurality of bonding pads includes configuring first pad configuration circuitry of the first die.

18. The method of claim 16, further comprising:
obtaining a second routing configuration associated with the first multiple nodes of the first circuitry and the first plurality of bonding pads;
selectively connecting, based on the second routing configuration, the first multiple nodes of the first circuitry to a second set of bonding pads of the first plurality of bonding pads, the second set of bonding pads different from the first set of bonding pads; and
communicating one or more signals between the first die and the second die via the second set of bonding pads.

19. The method of claim 16, further comprising:
communicating between first control circuitry of the first die and second control circuitry of the second die to synchronize communication between the first die and the second die; and
performing a test operation between the first die and the second die, wherein the test operation includes:
providing a first signal via a first conductive path between the first die and the second die; and
indicating whether the first conductive path is defective or available for use.

20. The method of claim 19, wherein:
obtaining the first routing configuration includes determining the first routing configuration based on the first conductive path being defective or available for use; and
the first routing configuration indicates a configuration of first pad configuration circuitry of the first die, second pad configuration circuitry of the second die, or a combination thereof.
